(19) United States
(12) Patent Application Publication
(10) Pub. No.: US 2025/0172589 A1
(43) Pub. Date: May 29, 2025

(54) PROBE SYSTEM, PROBE CARD, PROBE HEAD, AND PROBE FOR TESTING ELECTRONIC DEVICE UNDER TEST INTEGRATED ON A SEMICONDUCTOR WAFER, AND ELECTRONIC DEVICE UNDER TEST TESTED BY THE PROBE CARD

(71) Applicant: MPI CORPORATION, Zhubei City (TW)

(72) Inventors: Chin-Tien YANG, Zhubei City (TW); Hui-Pin YANG, Zhubei City (TW)

(21) Appl. No.: 18/932,714

(22) Filed: Oct. 31, 2024

Related U.S. Application Data
(60) Provisional application No. 63/547,179, filed on Nov. 3, 2023.

(51) Int. Cl. G01R 1/073; G01R 1/067; G01R 31/28

(52) U.S. Cl. CPC G01R 1/07342; G01R 1/06716; G01R 31/2886

(57) ABSTRACT

A probe head includes multiple probes and upper and lower guide plates. The probes pass through the upper and lower guide plates and include head, tail, and body portions. The head includes a contact area for contacting the contact pads on the DUT during testing. The body is located between the head and tail and extends along a longitudinal development axis. The transverse cross-section of the body is perpendicular to the longitudinal development axis and has a wide edge and a thick edge. The wide and thick edges represent the width and thickness of the body, respectively. The length of each probe is greater than the thickness of the body. The body has a multilayer structure, in which multiple layers are separated along the wide edge, and at least one slit divides these layers, with the thickness of the body being greater than or equal to its width.

### CROSS-REFERENCE TO RELATED APPLICATIONS

This application claims priority to U.S. Provisional Application No. 63/547,179 filed on Nov. 3, 2023, the contents of which are incorporated herein by reference.

### BACKGROUND OF THE INVENTION

The present invention relates to a probe system, a probe card, a probe head, a probe structure and an electronic device under test tested by the probe card. More specifically, the present invention relates to a probe system, a probe card, a probe head and a probe structure, which weaken the rigidity of the probe to make the probe meet the requirements of high-frequency/high-speed testing and high-current testing, and an electronic device under test tested by the probe card.

A probe card is a tool for testing electrical properties of a semiconductor wafer or a packaged device, and it may generally include at least a probe head, a space transformer and a circuit board. The probe head may include a plurality of probes, and each probe may make contact with a contact pad of an electronic device under test (DUT) integrated on a semiconductor wafer to test the electrical performance of the electronic device under test. The pattern of the contact pad varies in response to different types of contact areas on the head portion. For example, a contact pad with a bump pattern corresponds to a contact area with a blunt surface pattern, while a contact pad with a pad pattern corresponds to a contact area with a sharp pattern. During testing, the probe and the electronic device under test move relatively at a distance along the longitudinal development axis (i.e., the Z axis), that is, the probe moves vertically (also called overdrive/overtravel). Usually, the electronic device under test is carried by a chuck to move upward from the contact height to get closer to the probe, so that the contact area of the head portion of the probe contacts and presses the contact pad of the electronic device under test. This practice can ensure sufficient mechanical contact between the probe tip and the contact pad, and ensure good electrical connection between the probe and the electronic device under test. However, when the contact area of the head portion of the probe is pressing the contact pad of the electronic device under test in the above-mentioned mode, the difference in rigidity between different probes will affect the magnitude of the action force exerted by the contact area of the probe on the contact pad of the electronic device under test when the specific displacement (i.e., the vertical movement) is fixed. Specifically, under the same specific displacement (vertical movement), the higher the rigidity of the whole probe is, the greater the action force exerted by the probe on the contact pad will be. The greater the action force exerted by the contact area of the probe on the contact pad of the electronic device under test is, the higher the loss that may be caused by the probe on the contact pad and/or the probe itself (i.e., the contact area of the head portion) will be. Accordingly, the rigidity of the probe obviously will affect the probability that the probe causes excessive/inappropriate loss to the contact pad of the electronic device under test and/or the probe itself (i.e., the contact area of the head portion) during testing.

In recent years, the demand for high-frequency/high-speed testing of electronic devices under test is increasing day by day, and with the increase of data transmission rate during testing (e.g., from 50 to 60 gigabits per second (Gbps) to over 100 Gbps), the impedance matching between the whole probe head and the electronic devices under test has an increasingly significant influence on high-speed signal transmission. When the impedance of the test path (i.e., the signal transmission path) is not matched, the influence of return loss will become significant. In order to meet the requirements of high-frequency/high-speed testing, designers of probes expect to shorten the length of the probe to facilitate the transmission of high-frequency/high-speed signals. In addition to the requirements of high-speed/high-frequency testing, high-current testing is also an increasingly important testing direction in the art to which the present invention belongs. In order to meet the requirements of high-current testing, designers of probes expect to increase the thickness of the probe to facilitate the transmission of high current. However, shortening the length of the probe and increasing the thickness of the probe mentioned above are all practices that improve the overall rigidity of the probe. Nevertheless, as mentioned previously, the stronger the overall rigidity of the probe is, the higher the probability of causing excessive/inappropriate loss to the contact pad of the electronic device under test will be during testing, which even further causes damage to other parts of the electronic device under test. Accordingly, an urgent need exists in the art to provide a solution that can weaken the rigidity of the probe and meanwhile enable the probe to meet the requirements of high-frequency/high-speed testing and/or high current testing.

### SUMMARY OF THE INVENTION

In order to at least solve the above technical problems, the present invention provides a probe for physically contacting an electronic device under test. The probe may comprise a head portion, a tail portion and a body portion. The head portion may include a contact area, and the contact area may be configured to make contact with a corresponding contact pad on the electronic device under test during testing. The body portion is located between the head portion and the tail portion and may extend according to a longitudinal development axis. A transverse cross-section of the body portion is perpendicular to the longitudinal development axis. The transverse cross-section has a wide edge and a thick edge, and the wide edge may represent a width of the body portion, while the thick edge may represent a thickness of the body portion. A length of the probe is greater than the thickness of the body portion. The body portion has a multilayer structure, and the multilayer structure may comprise a plurality of layers and at least one slit. The plurality of layers are separated along the wide edge, the at least one slit divides the plurality of layers, and the thickness of the body portion is greater than or equal to the width of the body portion.

In order to at least solve the above technical problems, the present invention further provides a probe head of a probe system for testing an electronic device under test integrated on a semiconductor wafer. The probe head may comprise an upper guide plate unit, a lower guide plate unit and a plurality of probes. Each of the probes may comprise a head portion, a tail portion and a body portion. The head portion may comprise a contact area and the contact area may be configured to make contact with a corresponding contact pad on the electronic device under test during testing. Each of the upper guide plate unit and the lower guide plate unit may comprise a plurality of guide holes. Each of the guide holes in the upper guide plate unit is sized to accommodate the tail portion of each probe, and each of the guide holes in the lower guide plate unit is sized to accommodate the head portion of each probe. Each probe may pass through one of the plurality of guide holes included in the upper guide plate unit and one of the plurality of guide holes included in the lower guide plate unit simultaneously. The body portion of each probe is located between the head portion and the tail portion of the same probe and extends according to a longitudinal development axis. A transverse cross-section of the body portion of each probe is perpendicular to the longitudinal development axis. The transverse cross-section has a wide edge and a thick edge, and the wide edge may represent a width of the body portion, while the thick edge may represent a thickness of the body portion. The body portion of each probe has a multilayer structure, and the multilayer structure comprises a plurality of layers and at least one slit. The plurality of layers are separated along the wide edge of the transverse cross-section of the same probe, and the at least one slit divides the plurality of layers. A length of each probe is greater than the thickness of the corresponding body portion, and the thickness of the same body portion is greater than or equal to the width of the same body portion.

In order to at least solve the above technical problems, the present invention further provides a probe card of a probe system for testing an electronic device under test integrated on a semiconductor wafer. The probe card may comprise a circuit board; a space transformer and a probe head as described above. The space transformer may be arranged on the circuit board. The probe head may be arranged on the other side of the space transformer opposite to the circuit board, and a tail portion of each probe in a probe pair of the probe head may be configured to be electrically connected to the space transformer.

In order to at least solve the above technical problems, the present invention further provides a probe system for functional testing of an electronic device under test integrated on a semiconductor wafer. The probe system may comprise a chuck, a test apparatus and a probe card as described above. The chuck may be configured to support the semiconductor wafer. The test apparatus may be electrically connected with the electronic device under test and may be configured to establish an electrical test procedure. The probe card may be arranged in the test apparatus.

In order to at least solve the above technical problems, the present invention further provides an electronic device under test. A high-frequency test procedure is performed on the electronic device under test by using the probe card described above, the high-frequency test procedure uses a high-frequency signal for testing, and the high-frequency test procedure is a loopback test procedure.

According to the above description, the probe system and the probe card and the probe head in the probe system provided according to the present invention reduce the rigidity of the whole probe by virtue of the multilayer structure in the probe, so that the action force exerted on the contact pad by the head portion of the probe when it contacts the electronic device under test during testing can be reduced, and the possibility that the electronic device under test is damaged due to the contact with the probe during testing are indeed reduced. Accordingly, the invention allows the designer of the probe to increase the thickness of the probe and/or shorten the length of the probe in order to improve the electrical performance of the probe, thereby meeting the electrical requirements of high-speed (high-frequency) and/or high-current testing (the signal integrity can be improved). In addition, as compared to the traditional probe structure with the thickness of the body portion being smaller than the width, the probe structure provided according to the present invention can further weaken the rigidity of the probe as a whole through the proportion arrangement of the thickness and the width of the body portion. Specifically, under the same ratio of the cross-sectional area of the layer and the cross-sectional area of the slit (e.g., 7:3), in the probe structure provided according to the present invention, the smaller the width of the layer in the probe buckling direction is, the smaller the reaction force that can be obtained will be. This means that the action force exerted to the contact pad of the electronic device under test by the probe is smaller under the same probe vertical movement (i.e., overdrive/overtravel). At the same time, the smaller the width of the layer in the buckling direction is, the smaller the max principal stress accumulated in the bending area of the body portion of the probe will be. This means that the probe structure provided according to the present invention reduces the max principal stress accumulated in the bending area of the body portion under the same probe vertical movement. This means that the probe is less likely to break, which makes the probe more durable and have a longer service life. Accordingly, the problem that “when the probe with weakened rigidity is deformed due to pressure during operation, the risk of breakage of the probe itself is increased because the stress is likely to be accumulated in the deformed and bent area of the body portion” can also obviously be solved by the present invention. If the above mechanism provided according to the present invention is applied to more probes, then a higher improvement effect can be obtained.

The above content provides a basic description of the present invention, including the technical problems solved by the present invention, the technical means adopted by the present invention and the technical effects achieved by the present invention, and various embodiments of the present invention will be further illustrated hereinafter.

### BRIEF DESCRIPTION OF THE DRAWINGS

Shown as follows:

FIG. 1 illustrates a wafer testing system in which a probe card, a probe head and probes are located according to one or more embodiments of the present invention.

FIG. 2 illustrates a side-view structure of a probe according to one or more embodiments of the present invention.

FIG. 3 illustrates a part of a probe structure according to one or more embodiments of the present invention.

FIG. 4 illustrates the side-view structure and arrangement of a probe according to one or more embodiments of the present invention.

FIG. 5A illustrates a part of a probe structure according to one or more embodiments of the present invention.

FIG. 5B illustrates the way in which the geometric center lines of the head portion and the body portion are offset in the part shown in FIG. 5A.

FIG. 6 to FIG. 8 illustrate a transverse cross-section of a body portion of a probe according to one or more embodiments of the present invention.

FIG. 9A and FIG. 9B both illustrate various transverse cross-sections of body portions with the same area but different ratios of width to thickness.

FIG. 10 illustrates a way in which probes in a probe pair are offset by a guide plate unit in a probe head according to one or more embodiments of the present invention.

FIG. 11 illustrates a double-probe arrangement of a probe pair according to one or more embodiments of the present invention.

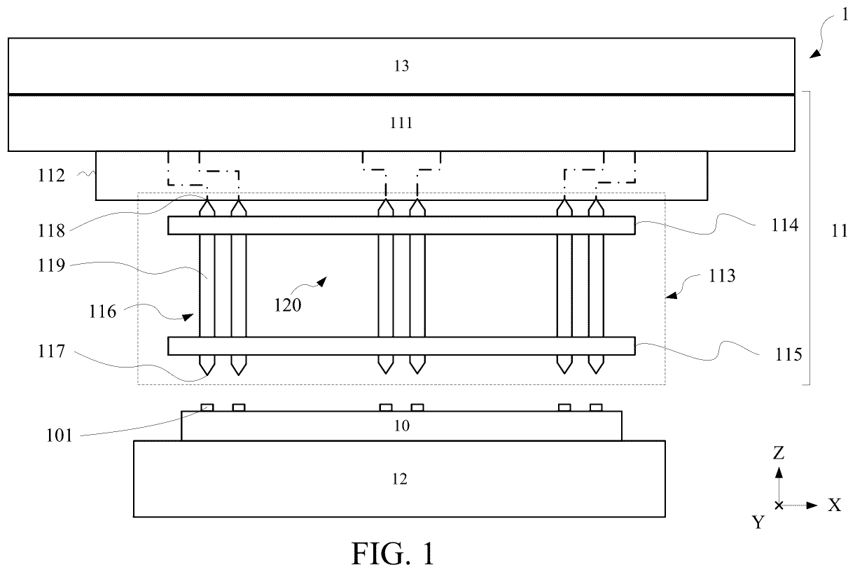

The contents shown in FIG. 1 to FIG. 11 only serve as exemplary examples for explaining the embodiments of the present invention, and are not intended to limit the scope claimed in the present invention.

### DETAILED DESCRIPTION OF THE INVENTION

The following embodiments are not intended to limit the claimed invention to a specific environment, application, structure, process, or situation. In the attached drawings, elements unrelated to the claimed invention will be omitted from depiction. In the attached drawings, dimensions of and dimensional scales among individual elements are provided only for illustration, and are not intended to limit the claimed invention. Unless otherwise specified, same reference numerals in the follow description may refer to the same elements.

Terminologies described here are only for the convenience of describing the content of embodiments, and are not intended to limit the claimed invention. Unless otherwise specified clearly, the singular form “a” or “an” shall be deemed to include the plural from. Terms such as “comprising”, “including” and “having” are used to specify the existence of features, integers, steps, operations, elements, components and/or groups stated after the terms, but do not exclude the existence or addition of one or more other additional features, integers, steps, operations, elements, components and/or groups or the like. The term “and/or” is used to indicate any one or all combinations of one or more associated items listed. When the terms “first”, “second” and “third” are used to describe elements, these terms are not intended to limit these elements described, but only to distinguish these elements. Therefore, for example, a first element may also be named as a second element without departing from the spirit or scope of the claimed invention.

Referring to FIG. 1, there is shown a probe system 1. The probe system 1 may at least comprise a probe card 11 and a chuck 12. The probe card 11 may be configured to electrically connecting and/or mechanically contacting an electronic device under test 10 to test the electrical performance of the electronic device under test 10. The probe card 11 may be configured to test the electronic device under test 10. The electronic device under test 10 may be a semiconductor wafer. The chuck 12 can be used to support the electronic device under test 10 for the probe card 11 to detect the electronic device under test 10. The electronic device under test 10 may include one or more contact pads (such as the contact pad 101 shown in FIG. 1), so that the contact area of each probe is configured to make contact with one of the one or more contact pads during the test of the electronic device under test 10 (a state where the contact area of each probe has not contacted the corresponding contact pad is shown in FIG. 1).

The probe card 11 may comprise a circuit board 111, a space transformer 112, and a probe head 113. The space transformer 112 may be arranged on the circuit board 111, and the probe head 113 may be arranged on the space transformer 112. The probe head 113 may basically comprise a plurality of probes and at least one guide plate, and one end of each probe may be electrically connected with the circuit board 111 through the space transformer 112, while the other end may be in contact with a contact pad (such as a metal pad or a conductor bump) on the electronic device under test 10 during testing. It shall be noted that the above-mentioned space transformer 112 is only described as being arranged on the circuit board 111 according to the respective conventional size relationships between the space transformer 112 and the circuit board 111, and it is not limited that the space transformer 112 must be located above the circuit board 111 in the physical sense.

The test apparatus 13 may perform various test procedures and/or communicate test information to the electronic device under test through the probe card 11. The test apparatus 13 may be, for example, a test head of a tester. Some test methods may include a loopback test procedure, in which the required high-frequency test signal is generated by the electronic device under test 10 itself, and then the signal is transmitted back to the electronic device under test 10 for testing after passing through the probe card 11, so as to determine whether the electronic device under test 10 operates normally.

The circuit board 111 may comprise a wafer side and a tester side. The wafer side of the circuit board 111 and the tester side of the circuit board 111 are arranged opposite to each other, and the tester side of the circuit board 111 is provided for connecting the test apparatus. In this embodiment, when the probe card 11 is used in the test apparatus 13, the wafer side may be the lower side of the circuit board 111, which may face the space transformer 112 and/or the electronic device under test 10, while the tester side may be the upper side of the circuit board 111, which may face away from the electronic device under test 10 and/or face the test apparatus 13. In this embodiment, the circuit board 111 is a general printed circuit board. The circuit board 111 has a top surface, a bottom surface and various signal lines provided therein, and contact pads electrically connected with the signal lines are formed on the top surface and the bottom surface. The contact pads on the top surface of the circuit board 111 are contacted through the pogo pin of the test apparatus. The test signal of the test apparatus may be transmitted to the bottom surface of the circuit board 111 through the signal lines described above.

The space transformer 112 may also comprise a wafer side and a tester side. It shall be noted here that the space transformer 112 may be composed of a multilayer circuit board. The tester side of the space transformer 112 may be connected to and arranged on the wafer side of the circuit board 111. In this embodiment, when the probe card 11 is used in the test apparatus 13, the wafer side of the space transformer 12 may be the lower side of the space transformer 112, which may face the probe head 113 and/or the electronic device under test 10, while the tester side of the space transformer 12 may be the upper side of the space transformer 112, which may face away from the electronic device under test 10, face the circuit board 111 and/or face the test apparatus 13. In this embodiment, the space transformer 112 may comprise a multilayer organic (MLO) carrier or a multilayer ceramic (MLC) carrier, and the material thereof may be adjusted according to actual requirements, which is not limited by the present invention. The space transformer 112 is provided with a variety of signal lines therein, and contact pads electrically connected with the internal signal lines are formed on the top and bottom surfaces of the space transformer 112, and the pitch between the contact pads on the top surface is greater than that between the contact pads on the bottom surface. The space transformer 112 is mechanically and electrically connected to the wafer side of the circuit board 111, i.e., the bottom surface of the circuit board 111, and the space transformer 112 is located below the circuit board 111 so that the contact pads on the top surface of the space transformer 112 can be electrically connected to the contact pads on the bottom surface of the circuit board 111 and the signal lines inside the space transformer 112 are electrically connected with the signal lines of the circuit board 111. It shall be noted here that for the connection between the space transformer 112 and the circuit board 111, the space transformer 112 may also be indirectly mechanically and/or electrically connected to the wafer side of the circuit board 111 through another carrier (e.g., a booster board).

The probe head 113 may be mechanically and/or electrically connected to the wafer side of the space transformer 112. As shown in FIG. 1, the probe head 113 may comprise an upper guide plate unit 114, a lower guide plate unit 115 and a plurality of probes (e.g., the probes 116 shown in FIG. 1). Each probe may physically contact the electronic device under test 10. The upper guide plate unit 114 may comprise at least one upper guide plate, and each of the at least one upper guide plate may be provided with a plurality of upper guide holes. The lower guide plate unit 115 may comprise at least one lower guide plate, and each of the at least one lower guide plate may be provided with a plurality of lower guide holes. The upper guide plate unit 114 and the lower guide plate unit 115 may be arranged vertically relative to each other along the longitudinal development axis (e.g., substantially along the direction of the coordinate axis Z (hereinafter referred to as “Z axis”) of the local reference system in FIG. 1). Each probe may pass through a corresponding one of the plurality of upper guide holes and a corresponding one of the plurality of lower guide holes.

The probes are usually made of special metals with good electrical and mechanical properties. By pressing the probe head 113 on the electronic device under test 10, good connection between the probe and the contact pad of the electronic device under test 10 can be ensured. During the pressing contact, the probe can slide in the corresponding guide holes on the upper and lower guide plate units, and the probe may be bent in the air gap 120 between the upper and lower guide plate units.

According to some embodiments of the present invention, the probes included in the probe head 113 may be probes that are called “buckling beams” in the art. That is, the body portion of the probe may have a constant transverse cross-section (for example which is substantially rectangular, preferably square or oblong) over its entire length, wherein the body of the probe is suitable for bending and/or stretching at a substantially central position, thereby being deformed during the testing of the electronic device under test 10. However, in some other embodiments, each of the probes does not necessarily have a constant transverse cross-section over its entire length.

The term “substantially rectangular” described herein refers to rectangular and other practical results that may be produced in order to make a rectangular transverse cross-section of the body portion, such as trapezoid. More specifically, as shall be appreciated by those of ordinary skill in the art, even if the apparatus for manufacturing the probe is designated to manufacture a probe with a rectangular transverse cross-section, the transverse cross-section of the actually manufactured probe may still have certain tolerances or manufacturing errors, so that the shape of the transverse cross-section of the body portion of the probe is not geometrically perfect rectangle in some embodiments.

The probe applicable to the present invention may at least include the form of a straight probe, such as a forming wire (FW), a MEMS wire (MW) or a pogo pin.

As shown in FIG. 1, each probe may comprise a head portion (e.g., the head portion 117 included in the probe 116), a tail portion (e.g., the tail portion 118 included in the probe 116), and a body portion (e.g., the body portion 119 included in the probe 116) located between the head portion and the tail portion. The head portion may end at the contact area and may be configured to abut against the corresponding contact pad of the electronic device under test 10 integrated in the semiconductor wafer (e.g., the head portion 117 shown in FIG. 1 is configured to abut against the contact pad 101 of the electronic device under test 10). The tail portion of each probe may pass through the guide hole on the upper guide plate unit 114 to be electrically connected to the space transformer 112. The tail portion may end at a contact bottom and may be configured to abut against a contact pad (not shown) of the space transformer 112. The body portion may extend substantially along the longitudinal development axis between the head portion and the tail portion. The head portion of each probe may be used to make electrical contact with the electronic device under test 10. The head of each probe may be configured for electrical communication and/or contact communication with the corresponding contact pad of the electronic device under test 10. The communication means that the probe may be configured to transmit the test signal of the probe card 11 to the electronic device under test 10 and/or to receive the signal from the electronic device under test 10.

Many embodiments of the present invention relate to at least different embodiments of the probe head 113, a probe structure in the probe head 113, and a probe card 11 comprising the probe head 113. It shall be noted, however, that although the probe structures in various embodiments of the present invention may be slightly different, the plurality of probes included in the probe head in various embodiments may all include at least one probe pair as a whole. In some embodiments, each probe pair may be used to transmit a set of differential signals, and thus such a probe pair may also be called a differential pair. In the preferred embodiment of the present invention, the differential pair may use two single-ended signal lines (e.g., P and N lines) to connect TX+ and RX+ as well as TX− and RX− respectively so as to transmit signals at the same time, and the two signals have the same signal voltage amplitude but opposite signal phases.

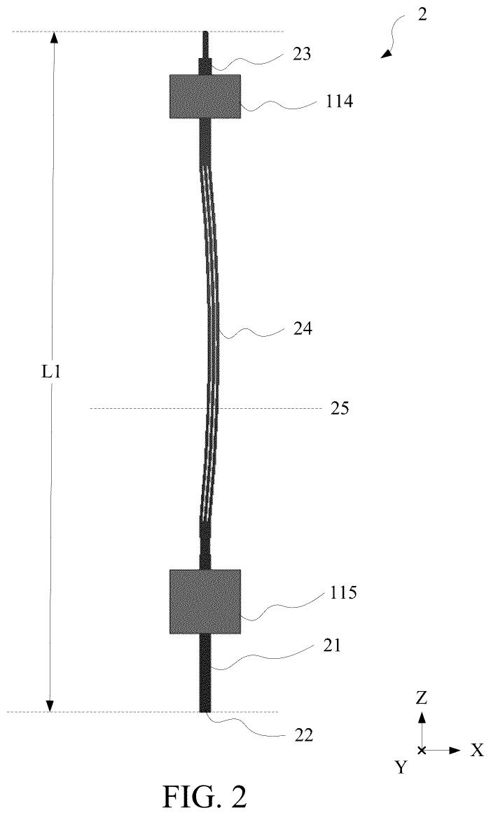

Taking the probe 2 as an example, FIG. 2 shows an example of the structure that each probe in the probe head 113 may have. Possible structures of each probe in the probe head 113 can be appreciated by those of ordinary skill in the art according to the description of the probe 2. First referring to FIG. 2, there is shown the side-view structure of the probe 2 from a perspective similar to that of FIG. 1. The probe 2 may have a long edge L1 (corresponding to the direction of the Z axis/longitudinal development axis in FIG. 2), a wide edge (corresponding to the direction of the coordinate axis X (hereinafter referred to as “X axis” for short) of the local reference system in FIG. 2, but the wide edge is not marked in the figure) and a thick edge (corresponding to the direction of the coordinate axis Y (hereinafter referred to as “Y axis” for short) of the local reference system in FIG. 2, but the thick edge is not marked in the figure). For the convenience of subsequent description, unless otherwise specified, it is defined that the long edge direction of each probe shown in FIG. 1 to FIG. 11 is the Z-axis direction, the wide edge direction of each probe is the X-axis direction, and the thick edge direction of each probe is the Y-axis direction.

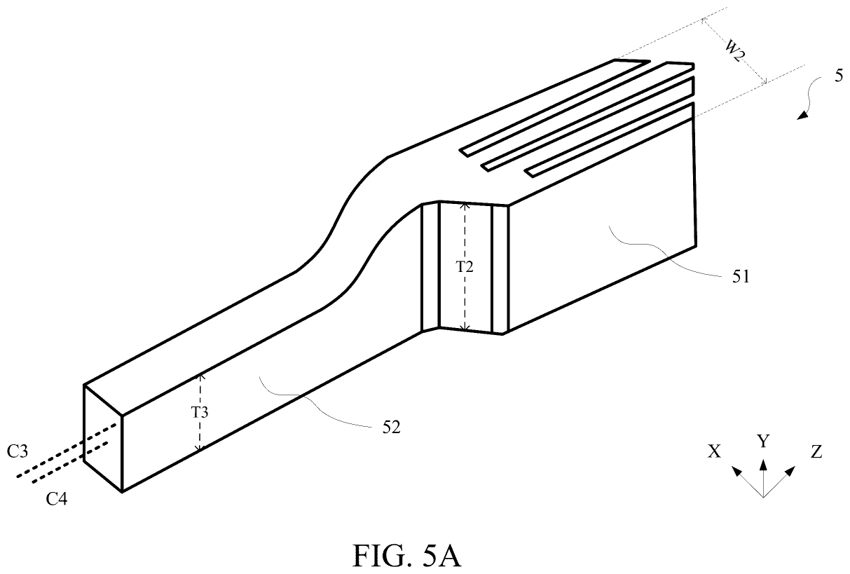

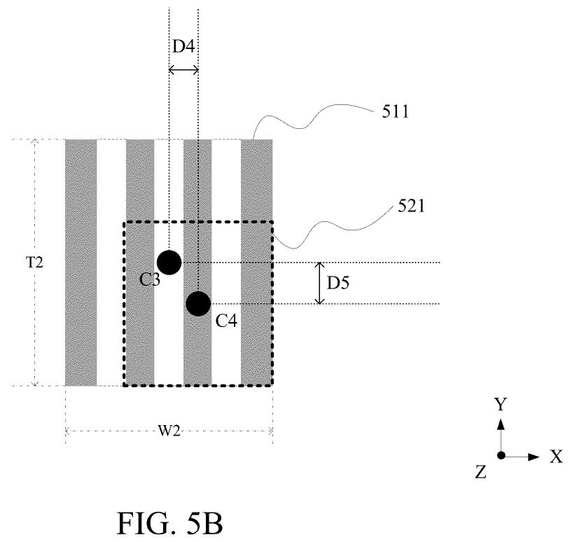

In some embodiments, the probe length of each probe in the probe head 113 according to the longitudinal development axis may be between 3 mm and 7 mm. In some embodiments, it may be not greater than 6 mm, and even preferably, it may be not greater than 4 mm. The wide edge and the thick edge of the probe 2 may be defined by the transverse cross-section cut to the body portion 24 through the reference plane 25 perpendicular to the long edge direction (i.e., the Z-axis direction). More specific similar examples of the transverse cross-section may be as shown in FIG. 5B to FIG. 9B described later.

When the probe 2 is arranged on the probe head 113, the head portion 21 of the probe 2 may pass through the guide hole on the lower guide plate unit 115, and the head portion 21 may comprise the contact area 22. The head portion 21 is configured to make contact with the electronic device under test 10 through the contact area 22 during the testing. In FIG. 2, the contact area 22 is exemplified as a blunt contact tip (i.e., the part contacting with the electronic device under test 10 is substantially flat), and the corresponding contact pad on the electronic device under test may have the pattern of a bump. The contact area 22 will contact and flatten the contact pad during the testing to ensure complete contact between the contact area 22 and the contact pad. However, this is not an absolute limitation to the form of the contact area and the corresponding contact pad. In addition, in some embodiments, the transverse cross-section of the head portion of each probe may be substantially rectangular (e.g., in the embodiment corresponding to the MEMS wire (also known as MW probe)).

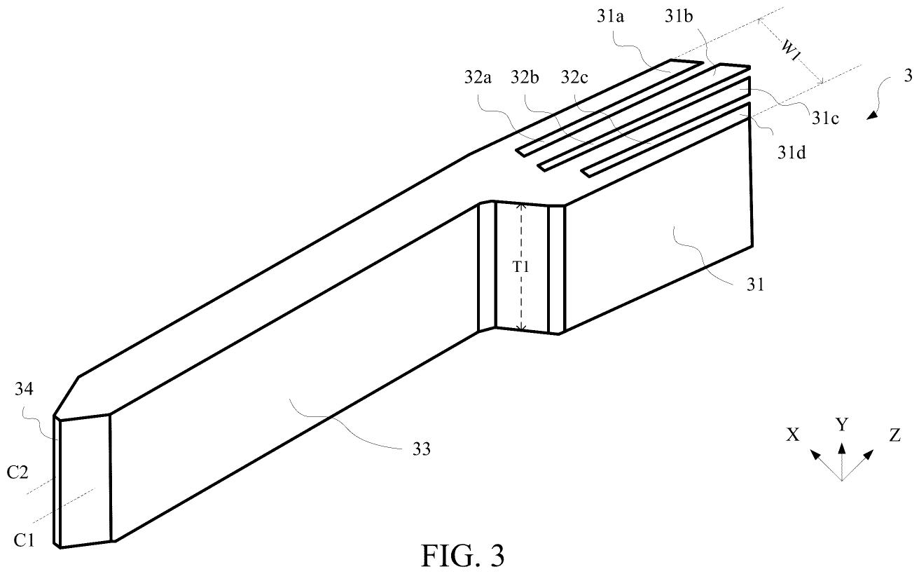

The tail portion 23 of the probe 2 may pass through the guide hole on the upper guide plate unit 114 to be electrically connected to the space transformer 112. The body portion 24 of the probe 2 may extend substantially along the longitudinal development axis between the head portion 21 and the tail portion 23. The body portion 24 may have a multilayer structure, and the multilayer structure may comprise a plurality of layers and at least one slit. A specific example of the multilayer structure may be as shown in FIG. 3 described later.

In some embodiments, the probe 2 may have a probe structure of a one-piece probe body, i.e., two end regions (i.e., the head portion 21 and the tail portion 23 in FIG. 2) and an intermediate region including the plurality of layers (i.e., the body portion 24 in FIG. 2) of the probe 2 may be assembled into a single piece.

Next, referring to FIG. 3, there is shown an aspect of the multilayer structure that the body portion of each probe in the probe head 113 may have, by taking a part of the probe 3 as an example. Possible structures of each probe in the probe head 113 can be appreciated by those of ordinary skill in the art according to the description of the probe 3. The long edge of the probe 3 may extend in the direction corresponding to the Z axis (i.e., the longitudinal development axis) similar to the long edge L1 in FIG. 2. However, the long edge of the probe 3 is not marked in FIG. 3 because the content shown in FIG. 3 is a part of the probe 3 that is close to the area of the head portion. The body portion 31 of the probe 3 may comprise a wide edge W1 and a thick edge T1. The length corresponding to the long edge of the probe 3 may be greater than the thickness corresponding to the thick edge T1, and the thickness may be greater than or equal to the width corresponding to the wide edge W1. Under the condition that the cross-sectional area of the body portion remains unchanged, the multilayer-structure probe with the thickness of the body portion greater than or equal to the width thereof provided according to the present invention provides significantly better rigidity weakening effect of the body portion than that of the multilayer-structure probe with the width greater than the thickness, and the weakening effect will be more obvious when the buckling direction of the probe is the width direction, and the relevant details will be detailed later.

The body portion 31 of the probe 3 may have a multilayer structure in which a plurality of layers 31a, 31b, 31c, and 31d are included, and these layers may be separated along the wide edge W1 of the body portion 31. For example, the layers 31a, 31b, 31c, and 31d may be divided by slits 32a, 32b, and 32c. It shall be understood that the number of the layers and slits shown in FIG. 3 (i.e., four layers and three slits) is only an example, and it is not an absolute limitation on the number of the layers and slits in the present invention. For example, the body portion of other probes may also comprise two layers and one slit, or three layers and two slits, and so on.

In some embodiments, the length of each layer (e.g., the length of each of the layers 31a, 31b, 31c and 31d measured along the Z-axis direction in FIG. 3) may be greater than the thickness of the same layer (e.g., the thickness of each of the layers 31a, 31b, 31c and 31d measured along the Y-axis direction in FIG. 3), and the thickness of the same layer may be greater than the width of the same layer (e.g., the width of each of the layers 31a, 31b, 31c and 31d measured along the X-axis direction in FIG. 3).

In some embodiments, the transverse cross-section of the plurality of layers in the body portion of each probe taken at one place on the longitudinal development axis (e.g., the Z axis in FIG. 3) (e.g., the cross section of the layers 31a, 31b, 31c and 31d of the body portion 31 of the probe 3 taken by the X-Y plane at a position on the Z axis in FIG. 3) may be substantially rectangular. In addition, in some embodiments, the areas and shapes of a plurality of transverse cross-sections of a plurality of layers on each probe taken at the same place on the longitudinal development axis (e.g., the Z axis in FIG. 3) may not be completely the same. In other words, among the plurality of layers, one or more layers may have rectangular transverse cross-sections, one or more layers may have trapezoidal transverse cross-sections, and even one or more layers may have irregular transverse cross-sections at the same place on the longitudinal development axis (e.g., the Z axis in FIG. 3), and the areas of these transverse cross-sections may not be completely the same. On the other hand, in some embodiments, the areas and shapes of a plurality of transverse cross-sections of each layer taken at different positions on the longitudinal development axis (e.g., the Z axis in FIG. 3) may also be not completely the same, i.e., the layer may have different sizes and/or shapes at different positions on the longitudinal development axis.

The multilayer structure of the body portion 31 of the probe 3 may reduce the overall rigidity of the probe 3, so that the pressure exerted by the contact area 34 of the head portion 33 of the probe 3 on the corresponding contact pad on the electronic device under test 10 is also reduced. In FIG. 3, the contact area 34 is illustrated as a relatively sharp contact tip, while the corresponding contact pad on the electronic device under test 10 may have the pattern of a pad. The contact area 34 will contact and puncture the contact pad during the testing so as to ensure the complete contact between the contact area 34 and the corresponding contact pad, but this is not an absolute limitation on the form of the contact area.

In some embodiments, the layers 31a, 31b, 31c and 31d may be bent into an arch or arc shape when the contact area 34 of the head portion 33 is pressed against the corresponding contact pad of the electronic device under test 10. In other words, each of the layers may be elastic. In these embodiments, the bending direction of each layer (i.e., the recess of the arch or arc shape) may be the same as the overall buckling direction of the probe 3, i.e., both of which are the wide edge direction of the probe 3 (e.g., the X-axis direction in FIG. 3). Because the overall buckling direction of the probe 3 is the wide edge direction, and the thickness (of the transverse cross-section) of the body portion 31 of the probe 3 is greater than the width, this structural arrangement can make the weakening effect of the overall rigidity of the probe relatively more remarkable as compared to the arrangement in which the buckling direction of the probe is the wide edge direction (e.g., the Y axis direction in FIG. 3). The buckling direction being the wide edge direction in the above description means that the probe takes the plane formed by the thick edge of the transverse cross-section of the body portion included therein (e.g., the body portion 31 of the probe 3) and the long edge of the same probe as the buckling surface.

In some embodiments, even if the contact area 34 of the probe head 33 is not pressed against the corresponding contact pad of the electronic device under test 10, the layers 31a, 31b, 31c, and 31d may still have an arch or arc shape. That is, the body portion 31 of the probe 3 in these embodiments may have a pre-deformed shape, and it may have a curved configuration at the still state where the probe 3 is not pressed to contact the contact pad of the electronic device under test 10.

In some embodiments, the length of each layer (i.e., the length measured on the layer along a direction parallel or substantially parallel to the long edge of the probe) may be greater than the width (i.e., the width measured on the layer along a direction parallel or substantially parallel to the wide edge of the probe) and/or the thickness (i.e., the thickness measured on the layer along a direction parallel or substantially parallel to the thick edge of the probe) of each layer. Furthermore, in some embodiments, the thickness of each layer may be greater than or equal to the width of the same layer, as is the case with the body portion.

In some embodiments, the geometric center line of the body portion 31 of the probe 3 may be aligned with the geometric center line of the head portion 33 without offset. However, in some other embodiments, as shown in FIG. 3, the body portion 31 of the probe 3 may have a geometric center line C1 while the contact area 34 (i.e., the tip of the probe) of the head portion 33 may have a geometric center line C2, and the geometric center line C2 is deviated from the geometric center line C1 in the direction of the wide edge W1 (i.e., the X-axis direction in FIG. 3). In other words, an interval may exist between the geometric center line C1 and the geometric center line C2 in the direction of the wide edge W1.

When the probe 3 and another probe together form a probe pair (i.e., a differential pair) for transmitting a set of differential signals, the geometric center line C2 may deviate from the geometric center line C1 in the direction away from the other probe on the X axis, which makes the pitch between the body portions of the two probes smaller than the center pitch between the contact areas of the head portions of the two probes. In detail, for a set of probe pair, the center pitch of the contact areas of the head portions of two probes needs to be the same as the pitch of the contact pads on the electronic device under test 10 in principle, and the pitch of the contact pads (or the pitch of two positions on the electronic device under test contacted by the contact areas of the probes during other tests) may not belong to the specifications that the probe manufacturer can determine by itself. By taking this into consideration, such structural arrangement with geometric center line offset can further shorten the pitch between the two body portions of two probes in a probe pair under the condition that the center pitch between the two contact areas remains unchanged, thereby improving the electrical performance of the probe pair as the differential pair.

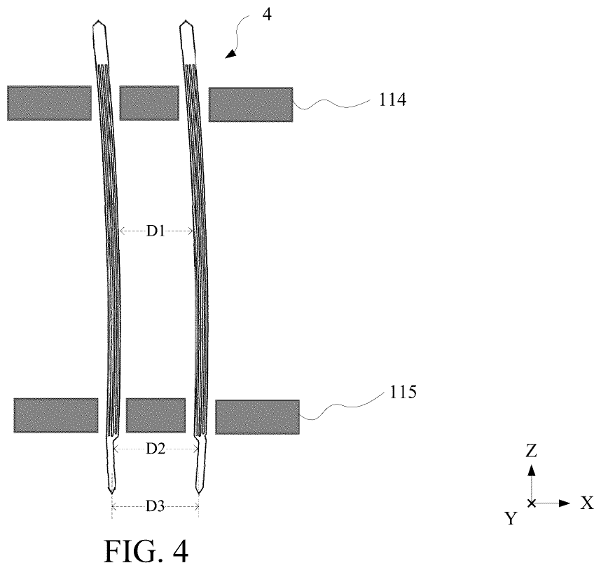

Reference may be made to FIG. 4 for a more specific example regarding shortening the pitch between the body portions of the probe pair as described above, and FIG. 4 shows a double-probe arrangement mode of each probe pair on the probe head 113 by taking a probe pair 4 as a differential pair on the probe head 113 as an example. Through the structural arrangement where the geometric center line of the body portion deviates from the geometric center line of the head portion in the wide edge direction, the body pitch D1 of two probes in the probe pair 4 may be smaller than the head pitch D2 of the contact areas and the center pitch D3 of the contact areas of the two probes.

In addition, although not shown in FIG. 4, in some embodiments, the pitch D3 between the contact areas of the two probes may be smaller than the head pitch D2, and the body pitch D1 may be even smaller than the center pitch D3 of the contact areas in addition to being smaller than the head pitch D2.

In some embodiments, the tip of the head portion of each probe may be thickened (not shown). Specifically, the thickness of the contact area (i.e., the contact tip, such as the contact area 22 of the probe 2 in FIG. 2) of the head portion of each probe on the probe head 113 in the direction of the connecting line between the probe centers of two probes in the probe pair to which the probe belongs may be greater than the thickness of the rest of the head portion (i.e., other portions except for the contact area) in the direction of the connecting line between the probe centers, and it may be even further greater than the thickness of the body portion of the probe in the direction of the connecting line between the probe centers in some embodiments. In other words, in these embodiments, the area of the transverse cross-section of the head portion of the probe may be larger than the area of the transverse cross-section of the body portion, and the area of the transverse cross-section of the contact area may be larger than the area of the transverse cross-section of the head portion. In order to achieve this result, the contact area of the head portion of the probe may be thickened in the production process (e.g., the whole contact tip may be covered and thickened as a whole, or only a part in the direction of the connecting line of the probe centers is thickened), but the way in which the contact area is thickened is not limited to electroplating. For example, for the MEMS wire, the contact area may be increased in thickness through a MEMS process. When the contact area of each probe is thickened, the contact area with the contact pad of the electronic device under test 10 will also be increased, thereby providing a more stable mode of contact. In particularly, when the manufacturer reduces the center pitch of each probe pair in order to reduce the reflection loss between the probe head 113 and the electronic device under test 10, the thickened contact area will still be able to normally contact the corresponding contact pad. The increase of the thickness of the thickened contact area may range from 1 to 5 microns, and preferably range from 1 to 2 microns. For example, taking the case where the contact area of a cobra is thickened (i.e., the diameter is increased) by electroplating as an example, when the thickness of the head portion of the probe is 50 microns, a thickness of 1 to 2 microns may be formed at the corresponding contact area so that the thickened contact area has a thickness of 52 to 54 microns.

Next, referring to FIG. 5A, there is shown another aspect of the multilayer structure that the body portion of each probe in the probe head 113 may have, by taking a part of the probe 5 as an example. Possible structures of each probe in the probe head 113 can be appreciated by those of ordinary skill in the art according to the description of the probe 5. The difference between the structure shown in FIG. 5A and that shown in FIG. 3 lies in that a geometric center line C3 of the body portion 51 of the probe 5 may be deviated from a geometric center line C4 of the head portion 52 of the probe 5 both in the direction corresponding to the wide edge W2 of the body portion 51 (i.e., the direction parallel to the X axis in FIG. 5A) and in the direction corresponding to the thick edge T2 of the body portion 51 (i.e., the direction parallel to the Y axis in FIG. 5A) so that intervals are formed therebetween respectively. This allows the thick edge T3 of the head portion 52 to be shorter than the thick edge T2 of the body portion 51.

Referring to FIG. 5B, there is further shown the offset between the geometric center line C3 and the geometric center line C4 in FIG. 5A from a top view. FIG. 5B shows a transverse cross-section 511 cut to the body portion 51 through the X-Y plane formed by the X axis and the Y axis, and a transverse cross-section 521 cut to the head portion 52 through another X-Y plane at a different height. The geometric center line C4 may deviate from the geometric center line C3 by a distance D4 in the positive direction of the X axis and deviate from the geometric center line C3 by a distance D5 in the negative direction of the Y axis. For the two probes of a probe pair as a differential pair, this structural arrangement may further allow the thickness corresponding to the thick edge T2 of the body portion 51 to be larger than the width corresponding to the wide edge W2 of the body portion 51 more significantly, in addition to the advantages described with respect to FIG. 3 (i.e., further increasing the possibility that the body portions are close to each other, i.e., the pitch between the body portions is shortened, under the condition where the pitch between the contact areas of the head portions may remain unchanged). In addition, the thickness of the thick edge T2 of the body portion 51 may be the same as that of at least one of the layers. For example, as shown in FIG. 5B, when the thicknesses of all the layers are the same, the thickness of the thick edge T2 of the body portion 51 may be the same as that of each layer.

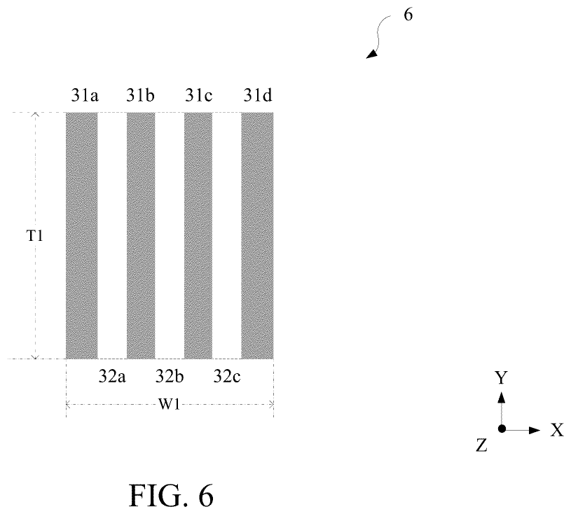

FIG. 6 to FIG. 8 illustrate several top views of the transverse cross-section of the body portion of each probe on the probe head 113. It shall be noted that the transverse cross-sections shown in FIG. 6 to FIG. 8 are all probe patterns that may be applicable in illustrating the probe system, probe card and probe head in the present invention, and the application scope of shapes, length-width ratios, and even sizes, positions and numbers of layers and/or slits thereof may not be limited to the probe patterns in the drawings to which they belong, and instead, they may be adapted to each other on the premise that there is no contradiction in implementation.

First referring to FIG. 6, there is shown a transverse cross-section 6 of the body portion 31 of the probe 3 in FIG. 3 on a reference plane. The reference plane is parallel to the X-Y plane formed by the X axis and the Y axis, and an example thereof may be the reference plane 25 as shown in FIG. 2. The transverse cross-section 6 may be rectangular, i.e., square (the length of the wide edge W1 of the body portion 31 is equal to the length of the thick edge T1 thereof) or oblong (the length of the wide edge W1 of the body portion 31 is not equal to the length of the thick edge T1 thereof).

In some embodiments, the layers 31a, 31b, 31c, 31d may have the same width as shown in FIG. 6, such as, but not limited to, 0.016 microns. In some embodiments, not only the layers have the same width, but the slits 32a, 32b, 32c may also have the same width as shown in FIG. 6, such as, but not limited to, 0.014 microns.

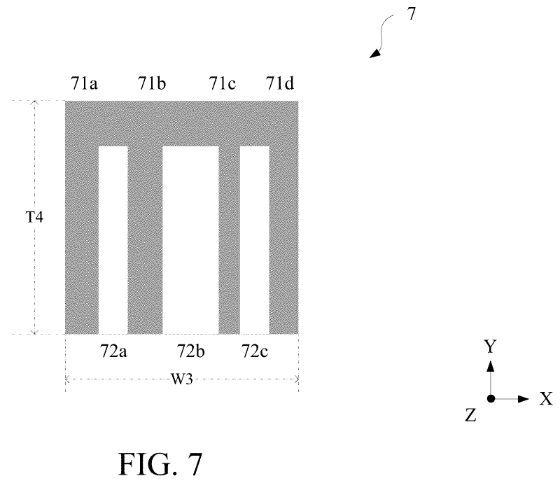

Next, referring to FIG. 7, there is shown a possible transverse cross-section of the body portion of each probe on the probe head 113 on the reference plane, by taking the transverse cross-section 7 of another probe as an example. The transverse cross-section 7 is the section of the body portion of another probe on the reference plane (i.e., the X-Y plane shown in FIG. 7, which is similar to the reference planes shown in FIG. 2 and FIG. 6). As shown in FIG. 7, the transverse cross-section 7 may be oblong, i.e., on the transverse cross-section 7, the length of the wide edge W3 of the body portion may be unequal to the length of the thick edge T4 of the same body portion, and the thickness corresponding to the thick edge T4 may be greater than or equal to the width corresponding to the wide edge W3.

The body portion of the probe corresponding to the transverse cross-section 7 may also be provided with a plurality of layers 71a, 71b, 71c and 71d and a plurality of slits 72a, 72b and 72c. In some embodiments, a plurality of widths and/or thicknesses corresponding to the slits on the body portion may not be completely the same or even completely different from each other. For example, in FIG. 7, the widths of the slits 72a, 72b and 72c are different. On the other hand, in some embodiments, a plurality of widths and/or thicknesses corresponding to a plurality of layers on the body portion of the probe may not be completely the same or even completely different from each other. For example, in FIG. 7, the widths of the layers 71a, 71b, 71c and 71d are not completely the same.

In addition, in some embodiments, a plurality of slits on the body portion of the probe may penetrate through the body portion in the thick edge direction. For example, the slits 32a, 32b and 32c shown in FIG. 6 penetrate through the body portion 31 in the Y axis direction. However, in some other embodiments, at least one of the plurality of slits on the body portion of the probe may not penetrate through the body portion in the thick edge direction. For example, the slits 72a, 72b and 72c shown in FIG. 7 meet the definition that at least one of the slits does not penetrate through the body portion in the Y-axis direction, or even no slit penetrates through the body portion. When no slit penetrates through the body portion, the body portion will take on a comb-like structure. In some other embodiments, the case where the slit does not penetrate through the body portion may only appear in part of the cross section. That is, on different reference planes on the body portion, some slits appear to penetrate through the body portion, while some slits do not penetrate through the body portion. In addition, the aspect where the slit does not penetrate the body portion is not limited to FIG. 7 (at a single side in the thick edge direction), and for example, the non-penetrating part may also be at the central position in the thick edge direction.

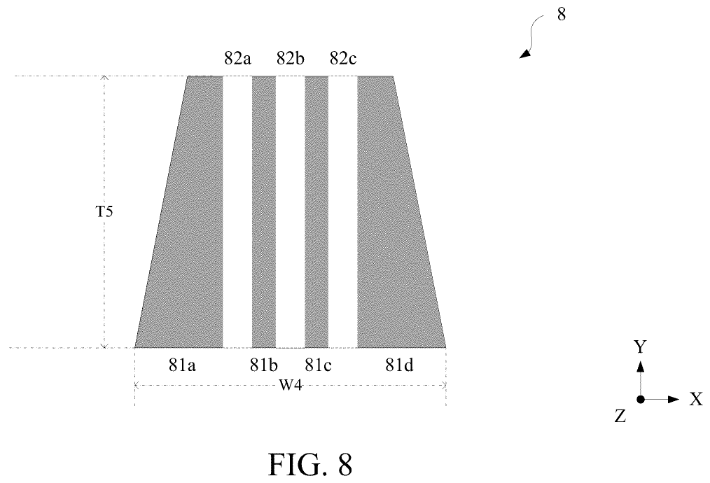

Next, referring to FIG. 8, there is shown a possible transverse cross-section of the body portion of each probe on the probe head 113 on the reference plane, by taking a transverse cross-section 8 of another probe as an example. The transverse cross-section 8 is the section of the body portion of another probe on the reference plane (i.e., the X-Y plane shown in FIG. 8, which is similar to the reference planes shown in FIG. 2, FIG. 6 and FIG. 7). As shown in FIG. 8, the transverse cross-section 8 may be the case that a rectangular transverse cross-section may actually appear (i.e., a substantially rectangular shape). In other words, there may be some imperfect right angles in the actual manufacturing results of rectangular probes, and FIG. 8 is illustrated in the form of approximate trapezoid. In such embodiments, the thick edge T5 of the body portion shown in the transverse cross-section 8 may be represented by the height of the trapezoid, while the wide edge W4 of the same body portion may be represented by the lower bottom of the trapezoid (i.e., the longer one of the upper bottom and the lower bottom). The thickness corresponding to the thick edge T5 may be greater than or equal to the width corresponding to the wide edge W4, i.e., the height of the trapezoid may be greater than or equal to the lower bottom. However, in some other embodiments, the wide edge of the body portion may also be represented by the upper bottom of the trapezoid (i.e., the shorter one of the upper bottom and the lower bottom) (although this is not shown in FIG. 8), and at this point, the height of the trapezoid may be greater than or equal to the lower bottom and greater than the upper bottom at the same time.

In addition, as shown in FIG. 8, the body portion of the probe corresponding to the transverse cross-section 8 may also be provided with a plurality of layers 81a, 81b, 81c, 81d and a plurality of slits 82a, 82b, 82c, and the layers 81a, 81b, 81c, 81d may be separated along the wide edge direction (i.e., the direction of the X axis shown in FIG. 8), and the slits 82a, 82b, 82c are used to divide the layers 81a, 81b, 81c, 81d. The slits 82a, 82b, and 82c may also penetrate through the body portion in the thick edge direction (i.e., the direction of the Y axis shown in FIG. 8).

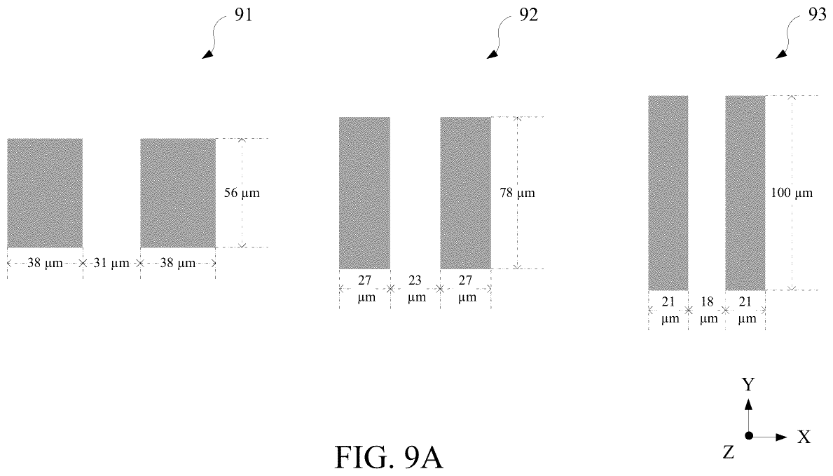

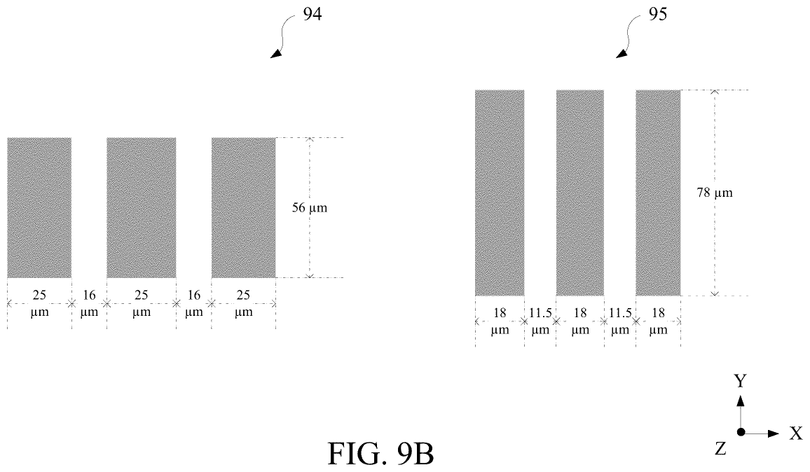

As previously mentioned for FIG. 3, under the condition that the cross-sectional area of the body portion remains unchanged, the multilayer-structure probe with the thickness of the body portion greater than or equal to the width thereof provided according to the present invention provides significantly better rigidity weakening effect of the body portion than that of the multilayer-structure probe with the width of the body portion greater than the thickness, and the weakening effect will be more obvious when the buckling direction of the probe is the width direction. A specific exemplary example may be as shown in FIG. 9A, which illustrates three transverse cross-sections 91, 92 and 93 of body portions with the same area but different ratios of thickness to width.

Referring to FIG. 9A, for the convenience of explanation, the transverse cross-sections 91, 92 and 93 are all presented in the form that two layers are separated from each other by one slit. In addition, in each of the transverse cross-sections 91, 92 and 93, the cross-sectional area ratio of the layer and the slit is maintained at 7:3, and the buckling direction of each probe (i.e., the direction in which the layer it bent during testing) is the direction corresponding to the wide edge, i.e., the X-axis direction in FIG. 9.

The relationships of the thickness (corresponding to the Y-axis direction in FIG. 9), width (corresponding to the X-axis direction in FIG. 9A) and slit width between the layers of the transverse cross-sections 91, 92 and 93, as well as the reaction forces corresponding to the three overtravels measured for the three transverse cross-sections at one end of the probe are shown in the following Table 1:

TABLE 1

| | Geometry (micron) | | | Reaction force (gf) | | |
|---|---|---|---|---|---|---|
| | | Slit | | Overtravel | Overtravel | Overtravel |
| | Thickness | width | Width | 100 microns | 125 microns | 150 microns |
| Transverse | 56 | 31 | 107 | 24.1 | 25.1 | 26.0 |
| cross-section 91 | | | | | | |
| Transverse | 78 | 23 | 77 | 12.4 | 13.0 | 13.6 |
| cross-section 92 | | | | | | |
| Transverse | 100 | 18 | 60 | 7.8 | 8.2 | 8.6 |
| cross-section 93 | | | | | | |

As can be seen from Table 1, among the three transverse cross-sections with different ratios of thickness to width of the body portions, a relatively largest reaction force is measured for the transverse cross-section 91 with the thickness of the body portion less than the width, i.e., the probe corresponding to the transverse cross-section 91 will exert the largest action force on the contact pad of the electronic device under test, no matter the overtravel is 100 microns, 125 microns or 150 microns. The reaction force measured for the transverse cross-section 92 with the thickness of the body portion equal to the width is lower, while the reaction force measured for the transverse cross-section 93 with the thickness of the body portion greater than the width is the lowest. As can be known from the above description, under the condition where the area ratio of the layer and the slit in the transverse cross-section remains unchanged (e.g., the ratio of the layer to the slit in FIG. 9A is 7 to 3), the smaller the width of the layer in the buckling direction is, the smaller the reaction force that can be obtained will be, i.e., the smaller the action force on the contact pad of the electronic device under test will be under the same overtravel.

In addition, the relationships of the thickness, width and slit width between the layers of the transverse cross-sections 91, 92 and 93, as well as the max principal stress corresponding to the three overtravels measured in the bending area of the body portion are shown in the following Table 2:

TABLE 2

| | Geometry (micron) | | | Max principal stress (MPa) | | |
|---|---|---|---|---|---|---|
| | | Slit | | Overtravel | Overtravel | Overtravel |
| | Thickness | width | Width | 100 microns | 125 microns | 150 microns |
| Transverse | 56 | 31 | 107 | 1363.5 | 1535.6 | 1694.9 |
| cross-section 91 | | | | | | |
| Transverse | 78 | 23 | 77 | 997.8 | 1115.7 | 1224.2 |
| cross-section 92 | | | | | | |
| Transverse | 100 | 18 | 60 | 803.9 | 895.8 | 980.2 |
| cross-section 93 | | | | | | |

As can be seen from Table 2, among the three transverse cross-sections with different ratios of thickness to width of the body portions, a relatively largest max principal stress is measured for the transverse cross-section 91 with the thickness of the body portion less than the width, i.e., the bending area of the body portion thereof has the largest accumulated stress during testing, no matter the overtravel is 100 microns, 125 microns or 150 microns. The max principal stress measured for the transverse cross-section 92 with the thickness of the body portion equal to the width is lower, while the max principal stress measured for the transverse cross-section 93 with the thickness of the body portion greater than the width is the lowest. This means that the probe corresponding to the transverse cross-section 93 is less likely to break during testing as compared to the probes corresponding to the other two transverse cross-sections, so it is relatively durable and has a relatively longer service life. The performance of the probe corresponding to the transverse cross-section 92 is inferior, and the performance of the probe corresponding to the transverse cross-section 91 is the least satisfactory.

Accordingly, the rigidity weakening effect of the body portion of the multilayer-structure probe with the thickness of the body portion greater than or equal to the width thereof provided according to the present invention is indeed significantly better than that of the multilayer-structure probe with the width of the body portion greater than the thickness thereof.

Next, referring to FIG. 9B, there is shown a transverse cross-section 94 and a transverse cross-section 95 obtained by changing the number of layers of the transverse cross-section 91 and the transverse cross-section 92 in FIG. 9A from two to three respectively. The Table 3 below shows the result changes in the measurement of the reaction force of the transverse cross-section 94 and the transverse cross-section 95 as compared to the transverse cross-section 91 and the transverse cross-section 92. The Table 4 below shows the result changes in the measurement of the max principal stress of the transverse cross-section 94 and the transverse cross-section 95 as compared to the transverse cross-section 91 and the transverse cross-section 92.

TABLE 3

| | Geometry (micron) | | | Reaction force (gf) | | |
|---|---|---|---|---|---|---|
| | | Slit | | Overtravel | Overtravel | Overtravel |
| | Thickness | width | Width | 100 microns | 125 microns | 150 microns |
| Transverse | 56 | 31 | 107 | 24.1 | 25.1 | 26 |
| cross-section 91 | | | | | | |
| Transverse | 56 | 16 | 107 | 11 | 11.3 | 12.1 |
| cross-section 94 | | | | | | |
| Transverse | 78 | 23 | 77 | 12.4 | 13 | 13.6 |
| cross-section 92 | | | | | | |
| Transverse | 78 | 11.5 | 77 | 6.1 | 6.3 | 6.7 |
| cross-section 95 | | | | | | |

TABLE 4

| | Geometry (micron) | | | Max principal stress (MPa) | | |
|---|---|---|---|---|---|---|
| | | Slit | | Overtravel | Overtravel | Overtravel |
| | Thickness | width | Width | 100 microns | 125 microns | 150 microns |
| Transverse | 56 | 31 | 107 | 1363.5 | 1535.6 | 1694.9 |
| cross-section 91 | | | | | | |
| Transverse | 56 | 16 | 107 | 962.7 | 1078.2 | 1185.5 |
| cross-section 94 | | | | | | |
| Transverse | 78 | 23 | 77 | 997.8 | 1115.7 | 1224.2 |
| cross-section 92 | | | | | | |
| Transverse | 78 | 11.5 | 77 | 711.9 | 794.7 | 870.6 |
| cross-section 95 | | | | | | |

As can be seen from Table 3 and Table 4 above, after changing the number of layers from two in the transverse cross-sections 91 and 92 to three in the transverse cross-sections 94 and 95, the reaction force corresponding to three overtravels measured at respective one end (e.g., the tail portion) is reduced by about 50% to 55%, and the max principal stress corresponding to three overtravels measured at the bending area of the respective body portion is reduced by about 28% to 30%. As can be known from the above description, under the condition where the area ratio of the layer and the slit in the transverse cross-section remains unchanged (e.g., the ratio of the layer to the slit in both FIG. 9A and FIG. 9B is 7 to 3), increasing the number of the layers may further reduce the reaction force, i.e., reduce the action force exerted on the contact pad of the electronic device under test under the same overtravel. In addition, increasing the number of the layers may further reduce the max principal stress, i.e., reduce the max principal stress in the bending area of the body portion under the same overtravel, which makes the probe less likely to break during testing and improves the durability of the probe.

Although FIG. 9B only shows the transverse cross-section 94 and the transverse cross-section 95 corresponding to the original transverse cross-section 91 and the transverse cross-section 92, according to the above description for the transverse cross-section 94 and the transverse cross-section 95, those of ordinary skill in the art shall directly understand that increasing the number of layers in the transverse cross-section 93 also has the advantages of reducing the reaction force and the max principal stress as mentioned above. Moreover, in combination with the advantage that the thickness of the transverse cross-section 93 itself is greater than the width, the effect of reducing the reaction force and the max principal stress for the transverse cross-section 93 after increasing the number of the layers is supposed to be the best among the three transverse cross-sections (i.e., the transverse cross-sections 91, 92 and 93).

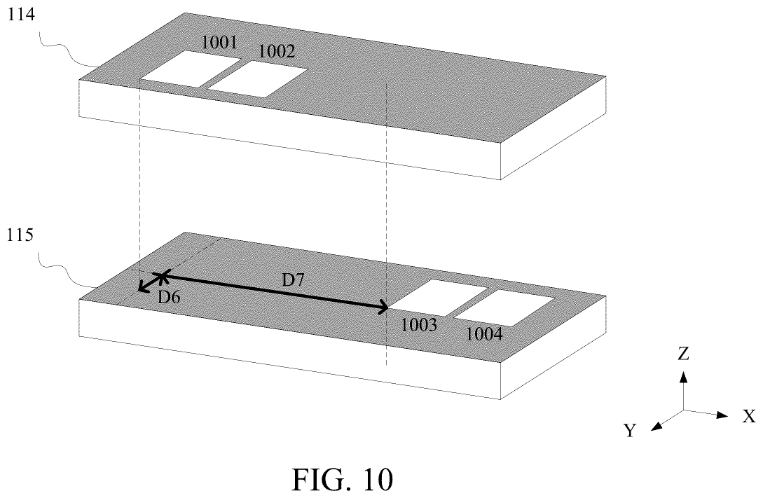

In some embodiments, two ends of each probe in each probe pair of the probe head 113 may be offset by the upper guide plate unit 114 and the lower guide plate unit 115, thereby assisting each probe in bending in the air gap 120. FIG. 10 illustrates a way in which a probe pair is offset by the upper guide plate unit 114 and the lower guide plate unit 115 in the probe head 113 shown in FIG. 1. Referring to FIG. 10, the upper guide plate unit 114 and the lower guide plate unit 115 respectively comprise a pair of upper guide holes 1001 and 1002 and a pair of lower guide holes 1003 and 1004 with rectangular (i.e., oblong or square) transverse cross-sections. The upper guide hole 1001 and the lower guide hole 1003 may be used to accommodate one probe in a probe pair as a differential pair, while the upper guide hole 1002 and the lower guide hole 1004 may be used to accommodate another probe in the same probe pair. Each guide hole comprises four guide hole walls, and among the four guide hole walls, a first guide hole wall is adjacent to and perpendicular to a second guide hole wall. When not pressed against the electronic device under test, each probe is held in the corresponding guide hole, so that one longitudinal side of the thick edge of each probe abuts against the first guide hole wall, and the other longitudinal side of the wide edge of the same probe abuts against the second guide hole wall.

Two ends of each probe may be offset by the upper guide plate unit 114 and the lower guide plate unit 115 by a distance D6 in a direction corresponding to the thick edges of the two probes (i.e., the direction of the Y axis in FIG. 10). In addition, in some embodiments, in addition to being offset in the thick edge direction, the two ends of each probe may further be offset by the upper guide plate unit 114 and the lower guide plate unit 115 by a distance D7 in a direction corresponding to the wide edge of the two probes (i.e., the direction of the X axis in FIG. 10). That is, the probe pair is obliquely offset, and the distance D7 may be greater than the distance D6.

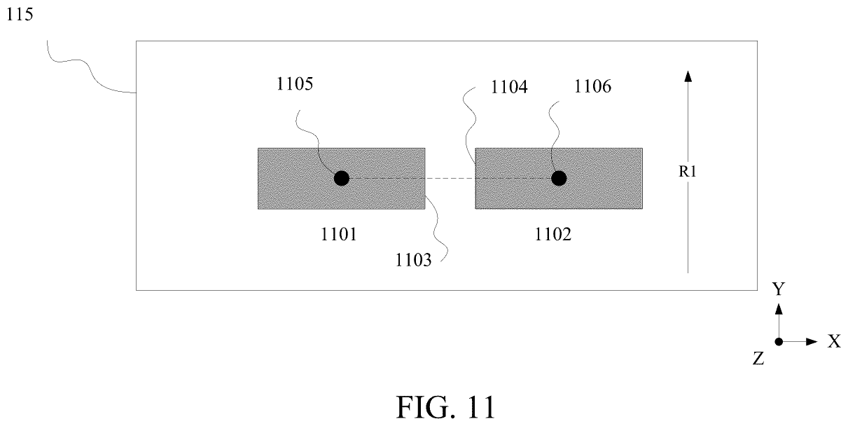

Referring to FIG. 11, there is shown an arrangement of each probe pair on the probe head 113 by taking the top view of a probe pair as a differential pair on the probe head 113 as an example. Two probes 1101, 1102 in the probe pair are arranged to respectively pass through two through holes in the lower guide plate unit 115 (the corresponding upper guide plate unit is not shown in the figure), and the two probes are opposite to each other with their respective wide edges 1103, 1104 (or the side where the wide edges 1103, 1104 are located in the long edge direction of the probes). The two probes 1101 and 1102 correspond to the same buckling direction R1, and the buckling direction R1 is perpendicular to a connecting line direction of the two probes (e.g., a connecting line direction of the two head portions, i.e., the X-axis direction in FIG. 11). More specifically, the buckling direction R1 is perpendicular to an axis formed by geometric centers 1105 and 1106 of the body portion sections of the respective probes 1101 and 1102. As compared to the arrangement in which the buckling directions are the same but both of them are for example in the X-axis direction, the above arrangement corresponding to FIG. 11 can shorten the minimum allowable pitch between the body portions of the two probes because there is no need to worry about the possibility of collision between the two probes due to buckling in the testing process. Shortening the pitch between the two probes is beneficial for improving the electrical performance of the probe, in particular, improving the impedance matching when detecting the electronic device under test with the pair of probes, so as to reduce a reflection loss between the probe head and the electronic device under test. For example, this method may shorten the body pitch between the two probes from 150 microns allowed originally to 126 microns.

According to the above descriptions, the multilayer structure in the probe provided according to the present disclosure can effectively reduce the overall rigidity performance of the probe during actual testing, so that the pressure exerted by the contact area of the head portion of the probe on the contact pad of the electronic device under test can be correspondingly reduced. This not only reduces the probability that the electronic device under test gets damaged due to the testing, but also allows the designer to increase the thickness of the probe and/or shorten the length of the probe in order to improve the electrical performance of the probe, thereby meeting the electrical requirements of high-speed (high-frequency) testing (the signal integrity can be improved) and/or high-current testing. If the above mechanism provided according to the present invention is applied to more groups of probe pairs with differential signals, higher improvement effect can be obtained.

The above disclosure is related to the detailed technical contents and inventive features thereof. People of ordinary skill in the art may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A probe for physically contacting an electronic device under test, comprising a head portion, a tail portion and a body portion, wherein:
the head portion includes a contact area, which is configured to make contact with a corresponding contact pad on the electronic device under test during testing;
the body portion is located between the head portion and the tail portion and extends according to a longitudinal development axis;
a transverse cross-section of the body portion is perpendicular to the longitudinal development axis, wherein the transverse cross-section has a wide edge and a thick edge, the wide edge represents a width of the body portion, while the thick edge represents a thickness of the body portion;
a length of the probe is greater than the thickness of the body portion; and
the body portion has a multilayer structure which comprises a plurality of layers and at least one slit, wherein the plurality of layers are separated along the wide edge, the at least one slit divides the plurality of layers, and the thickness of the body portion is greater than or equal to the width of the body portion.

2. The probe according to claim 1, wherein:
a length of each layer among the plurality of layers is greater than a thickness of the same layer;
the thickness of the same layer is greater than a width of the same layer; and
the thickness of the body portion is equal to the thickness of at least one of the plurality of layers.

3. The probe according to claim 1, wherein:
when the contact area of the head portion is pressed against the electronic device under test, the plurality of layers are bent into an arch shape; and
a bending direction of the plurality of layers is a direction corresponding to the wide edge.

4. The probe according to claim 3, wherein the plurality of layers are also arched even when the contact area of the head portion is not pressed against the electronic device under test.

5. The probe according to any of claim 1, wherein the transverse cross-section of the body portion is substantially rectangular or substantially trapezoidal.

6. The probe according to any of claim 1, wherein a transverse cross-section of at least one of the plurality of layers is substantially rectangular or substantially trapezoidal.

7. The probe according to claim 1, wherein the probe comprises a plurality of slits, and a plurality of widths corresponding to the plurality of slits are not completely the same with each other.

8. The probe according to claim 1, wherein a plurality of widths corresponding to the plurality of layers are not completely the same with each other.

9. The probe according to claim 1, wherein at least one of the areas and cross-sectional shapes of a plurality of transverse cross-sections of at least one of the plurality of layers on the longitudinal development axis are not completely the same with each other.

10. The probe according to claim 1, wherein at least one of the areas and cross-sectional shapes of a plurality of transverse cross-sections corresponding to the plurality of layers on the longitudinal development axis are not completely the same with each other.

11. The probe according to claim 1, wherein a first interval exists between a body geometric center line of the body portion and a head geometric center line of the head portion in a direction corresponding to the wide edge of the body portion, and a second interval exists between the body geometric center line and the head geometric center line in a direction corresponding to the thick edge of the body portion.

12. The probe according to claim 1, wherein a transverse cross-section of the head portion is substantially rectangular.

13. A probe head of a probe system for testing an electronic device under test integrated on a semiconductor wafer, comprising an upper guide plate unit, a lower guide plate unit and a plurality of probes, wherein:
each of the probes comprises a head portion, a tail portion and a body portion, wherein the head portion comprises a contact area and the contact area is configured to make contact with a corresponding contact pad on the electronic device under test during testing;
each of the upper guide plate unit and the lower guide plate unit comprises a plurality of guide holes, each of the guide holes in the upper guide plate unit is sized to accommodate the tail portion of each probe, each of the guide holes in the lower guide plate unit is sized to accommodate the head portion of each probe, and each probe passes through one of the plurality of guide holes included in the upper guide plate unit and one of the plurality of guide holes included in the lower guide plate unit simultaneously;
the body portion of each probe is located between the head portion and the tail portion of the same probe and extends according to a longitudinal development axis;
a transverse cross-section of the body portion of each probe is perpendicular to the longitudinal development axis, wherein the transverse cross-section has a wide edge and a thick edge, the wide edge represents a width of the body portion, while the thick edge represents a thickness of the body portion;
the body portion of each probe has a multilayer structure, the multilayer structure comprises a plurality of layers and at least one slit, wherein the plurality of layers are separated along the wide edge of the transverse cross-section of the same probe, and the at least one slit divides the plurality of layers; and
a length of each probe is greater than the thickness of the body portion of the same probe, and the thickness of the same body portion is greater than or equal to the width of the same body portion.

14. The probe head according to claim 13, wherein two ends of each probe are offset by a first distance through the upper guide plate unit and the lower guide plate unit in a thick edge direction corresponding to the body portion of the same probe.

15. The probe head according to claim 14, wherein:
the two ends of each probe are further offset by a second distance through the upper guide plate unit and the lower guide plate unit in a wide edge direction corresponding to the body portion of the same probe; and
the second distance is greater than the first distance.

16. The probe head according to claim 13, wherein the plurality of probes comprise at least one probe pair, and a body pitch of each probe pair is smaller than a head pitch of the same probe pair.

17. The probe head according to claim 13, wherein the plurality of probes comprise at least one probe pair, and a body pitch of each probe pair is smaller than a center pitch of two contact areas of two head portions of the same probe pair.

18. The probe head according to claim 13, wherein a body geometric center line and a head geometric center line of each probe have a first interval therebetween in a wide edge direction corresponding to the body portion of the same probe, and have a second interval therebetween in a thick edge direction corresponding to the body portion of the same probe.

19. The probe head according to claim 13, wherein a transverse cross-section of each guide hole is substantially rectangular.

20. The probe head according to claim 13, wherein:
among the plurality of layers included in each probe, a length of each layer is greater than a thickness of the same layer, the thickness of the same layer is greater than a width of the same layer, and the thickness of the body portion includes a plurality of thicknesses corresponding to the plurality of layers.

21. The probe head according to claim 13, wherein:
the plurality of layers included in each probe are bent into an arch shape when the contact area of the head portion of the same probe is pressed against the electronic device under test; and
a bending direction of the plurality of layers included in each probe is a wide edge direction corresponding to the body portion of the same probe.

22. The probe head according to claim 21, wherein the plurality of layers included in each probe are also arched even when the contact area of the head portion of the same probe is not pressed against the electronic device under test.

23. The probe head according to claim 13, wherein the transverse cross-section of the body portion of each probe is substantially rectangular or substantially trapezoidal.

24. The probe head according to claim 13, wherein the number of the at least one slit included in each probe is plural, and a plurality of widths corresponding to the plurality of slits included in each probe are not completely the same with each other.

25. The probe head according to claim 13, wherein a plurality of widths corresponding to the plurality of layers included in each probe are not completely the same with each other.

26. The probe head according to claim 13, wherein:
each probe takes a plane formed by the thick edge of the transverse cross-section of the body portion included in the probe and a long edge of the same probe as a buckling surface;
the plurality of probes comprise at least one probe pair, and two probes in each probe pair have the same buckling direction; and
the two probes in each probe pair face each other with a plane formed by the wide edge of the transverse cross-section of the respective body portion and a long edge of the same probe, and the buckling direction of the two probes is perpendicular to a connecting line direction of the two head portions of the two probes, thereby shortening a minimum allowable pitch between the body portions of the two probes.

27. A probe card of a probe system for testing an electronic device under test integrated on a semiconductor wafer, comprising:
a circuit board;
a space transformer, being arranged on the circuit board; and
the probe head according to claim 13, being arranged on the other side of the space transformer opposite to the circuit board, and the tail portion of each probe among the plurality of probes in the probe head is configured to be electrically connected to the space transformer.

28. A probe system for functional testing of an electronic device under test integrated on a semiconductor wafer, comprising:
a chuck, being configured to support the semiconductor wafer;
a test apparatus, being configured to be electrically connected with the electronic device under test for establishing an electrical test procedure; and
the probe card according to claim 27, being arranged in the test apparatus.

29. An electronic device under test, on which a high-frequency test procedure is performed using the probe card according to claim 27, wherein the high-frequency test procedure uses a high-frequency signal for testing, and the high-frequency test procedure is a loopback test procedure.
